(19) United States
(12) Patent Application Publication
(10) Pub. No.: US 2023/0204823 A1
(43) Pub. Date: Jun. 29, 2023

(54) OPTICAL FILM, POLARIZING PLATE COMPRISING THE SAME, AND OPTICAL DISPLAY APPARATUS COMPRISING THE SAME

(71) Applicant: SAMSUNG SDI CO., LTD., Yongin-si (KR)

(72) Inventors: Jung Hun YOU, Suwon-si (KR); Yoon Jung KIM, Suwon-si (KR); Kyu Sik KIM, Suwon-si (KR); Kwang Ho SHIN, Suwon-si (KR); Jun Mo KOO, Suwon-si (KR); Sang Hum LEE, Suwon-si (KR)

(21) Appl. No.: 18/089,263

(22) Filed: Dec. 27, 2022

(30) Foreign Application Priority Data
Dec. 27, 2021 (KR) 10-2021-0188138

(51) Int. Cl. G02B 1/14; G02B 1/04; G02B 1/18; G02B 5/30; H10K 50/80

(52) U.S. Cl. CPC G02B 1/14; G02B 1/04; G02B 1/18; G02B 5/3083; H10K 50/868

(57) ABSTRACT

An optical film, a polarizing plate including the same, and an optical display apparatus including the same are disclosed. An optical film includes: a third layer, a second primer layer, a first layer, a first primer layer, and a second layer sequentially stacked in the stated order, and each of the first primer layer and the second primer layer has a glass transition temperature (Tg) of 50° C. to 100° C. and is a (meth)acrylate primer layer.

### CROSS-REFERENCE TO RELATED APPLICATION

This application claims priority to and the benefit of Korean Patent Application No. 10-2021-0188138, filed on Dec. 27, 2021 in the Korean Intellectual Property Office, the entire disclosure of which is incorporated herein by reference.

### BACKGROUND

### 1. Field

Aspects of embodiments of the present invention relate to an optical film, a polarizing plate including the same, and an optical display apparatus including the same.

### 2. Description of the Related Art

An organic light emitting diode display can suffer from deterioration in visibility and contrast due to reflection of external light. To solve this problem, a polarizing plate including a polarizer and a retardation film may be stacked on a light emitting device panel. The retardation film is interposed between the polarizer and the light emitting device panel. The retardation film is generally composed of at least two retardation layers having different phase retardations to achieve more complete antireflection.

However, the at least two layers constituting the retardation film are formed of different materials. Accordingly, the retardation film formed by bonding the layers to each other is required to have good reliability and good durability. In recent years, a technique for reduction in thickness of the retardation film has been developed in the art by coating a coating layer composition to a predetermined thickness on one surface of any one layer, followed by drying the composition to form a retardation layer, instead of bonding the layers using a bonding agent. Here, the retardation film including at least two layers is also required to have good reliability and durability.

The background technique of the present invention is disclosed in KR Patent Laid-open Publication No. 10-2013-0103595 and the like.

### SUMMARY

According to an aspect of embodiments of the present invention, an optical film that exhibits good properties in terms of durability upon dipping testing in hot water, heat resistance durability, and humid-heat resistance reliability is provided.

According to another aspect of embodiments of the present invention, an optical film that has good interlayer peel strength and low haze is provided.

According to another aspect of embodiments of the present invention, a polarizing plate that has good properties in terms of heat resistance durability and humid-heat resistance reliability is provided.

According to an aspect of some embodiments of the present invention, an optical film is provided.

According to one or more embodiments, an optical film includes: a third layer, a second primer layer, a first layer, a first primer layer, and a second layer sequentially stacked in the stated order, wherein each of the first primer layer and the second primer layer has a glass transition temperature (Tg) of 50° C. to 100° C. and is a (meth)acrylate based primer layer.

In one or more embodiments, the first layer may include a hydrophobic retardation film.

In one or more embodiments, the hydrophobic retardation film may include at least one selected from among a cyclic olefin polymer (COP) based film and a cyclic olefin copolymer (COC) based film.

In one or more embodiments, the second layer may include a non-liquid crystal layer having an in-plane retardation of 70 nm to 120 nm at a wavelength of 550 nm.

In one or more embodiments, the third layer may include a non-liquid crystal positive C retardation layer.

In one or more embodiments, each of the second layer and the third layer may include at least one selected from among a polystyrene based polymer and a cellulose based polymer.

In one or more embodiments, each of the polystyrene based polymer and the cellulose based polymer may contain one or more halogen.

In one or more embodiments, the halogen may be fluorine.

In one or more embodiments, the first layer may have a lower glass transition temperature and a higher Young's modulus than each of the second layer and the third layer.

In one or more embodiments, the (meth)acrylate based primer layer may be formed of a primer layer composition including a copolymer of a monomer mixture including a (meth)acrylic monomer having a glass transition temperature of 10° C. to 100° C. in a homopolymer phase.

In one or more embodiments, the (meth)acrylic monomer may include an alkyl group-containing (meth)acrylic ester.

In one or more embodiments, the monomer mixture may further include a peel strength-enhancing compound.

In one or more embodiments, the peel strength-enhancing compound may include at least one selected from among methyl (meth)acrylate, ethyl (meth)acrylate, n-propyl (meth)acrylate, iso-propyl (meth)acrylate, n-butyl (meth)acrylate, iso-butyl (meth)acrylate, t-butyl (meth)acrylate, n-hexyl (meth)acrylate, 2-ethylhexyl (meth)acrylate, isobornyl (meth)acrylate, cyclohexyl (meth)acrylate, n-octyl (meth)acrylate, n-hexyl (meth)acrylate, lauryl (meth)acrylate, stearyl (meth)acrylate, butyl acetic ester, butyl formic ester, 2-methyl-2-propenoic acid cyclohexyl ester, 2-propenoic acid 2-methyl-cyclohexyl ester, and isopropyl acetate.

In one or more embodiments, the peel strength-enhancing compound may include at least one selected from among butyl acetic ester, butyl formic ester, 2-methyl-2-propenoic acid cyclohexyl ester, 2-propenoic acid 2-methyl-cyclohexyl ester, and isopropyl acetate.

In one or more embodiments, the primer layer composition may further include at least one selected from among a peel strength-enhancing compound and a curing agent.

In one or more embodiments, the optical film may have a haze of 0.3% or less, a peel strength of 300 gf/25 mm or more between the first layer and the second layer, and a peel strength of 300 gf/25 mm or more between the first layer and the third layer.

According to an aspect of some embodiments of the present invention, a polarizing plate is provided.

In one or more embodiments, a polarizing plate includes a polarizer and the optical film according to an embodiment of the present invention on at least one surface of the polarizer.

According to an aspect of some embodiments of the present invention, an optical display apparatus is provided.

In one or more embodiments, an optical display apparatus includes the polarizing plate according to an embodiment of the present invention.

According to an aspect of the present invention, an optical film is provided that exhibits good properties in terms of durability upon dipping testing in hot water, heat resistance durability, and humid-heat resistance reliability.

According to another aspect of the present invention, an optical film is provided that has good interlayer peel strength and low haze.

According to another aspect of the present invention, a polarizing plate is provided that has good properties in terms of heat resistance durability and humid-heat resistance reliability.

### BRIEF DESCRIPTION OF THE DRAWINGS

FIG. 1 is a cross-sectional view of an optical film according to an embodiment of the present invention.

FIG. 2 is a cross-sectional view of a polarizing plate according to another embodiment of the present invention.

### DETAILED DESCRIPTION

Herein, some embodiments of the present invention will be described in further detail with reference to the accompanying drawings to provide a thorough understanding of the invention to those skilled in the art. It is to be understood, however, that the present invention may be embodied in various ways and is not limited to the following embodiments.

In the drawings, components unrelated to the description may be omitted for clear description of the invention, and like components are denoted by like reference numerals throughout the specification. Although lengths, thicknesses, or widths of various components may be exaggerated for understanding in the drawings, the present invention is not limited thereto.

Herein, “in-plane retardation (Re),” “out-of-plane retardation (Rth),” and “degree of biaxiality (NZ)” are represented by the following Equations A, B, and C, respectively:

Re=(nx−ny)×d; [Equation A]

Rth=((nx+ny)/2−nz)×d; [Equation B]

NZ=(nx−nz)/(nx−ny), [Equation C]

where nx, ny, and nz are indexes of refraction of an optical device in the slow axis direction, the fast axis direction, and the thickness direction of the optical device at a measurement wavelength, respectively, and d is the thickness of the optical device (unit: nm). In Equations A to C, the measurement wavelength may be 450 nm, 550 nm, or 650 nm.

Herein, “short wavelength dispersion” refers to Re(450)/Re(550) and “long wavelength dispersion” refers to Re(650)/Re(550), wherein Re(450), Re(550), and

Re(650) refer to in-plane retardation (Re) of a single retardation layer or a laminate of retardation layers at wavelengths of 450 nm, 550 nm, and 650 nm, respectively.

As used herein to represent an angle, “+” means a counterclockwise direction, and “−” means a clockwise direction.

Herein, “(meth)acryl” may mean acryl and/or methacryl.

Herein, “modulus” refers to Young's modulus and indicates a degree of deformation of a measurement target depending upon pressure, as measured by a tensile test method at 25° C.

As used herein to represent a specific numerical range, “X to Y” means “greater than or equal to X and less than or equal to Y (X≤ and ≤Y).”

An optical film according to one or more embodiments of the present invention is an optical film laminate that includes a third layer, a second primer layer, a first layer, a first primer layer, and a second layer sequentially stacked in the stated order. The first layer and the third layer are closely connected to each other by the second primer layer, and the first layer and the second layer are closely connected to each other by the first primer layer.

Each of the first primer layer and the second primer layer has a glass transition temperature of 50° C. to 100° C. and is a (meth)acrylate based primer layer.

The optical film according to one or more embodiments of the present invention has a haze of 0.3% or less and exhibits good properties in terms of durability upon dipping testing in hot water, heat resistance durability, and humid-heat resistance reliability. As described below, the optical film according to the present invention is applied to a polarizing plate for antireflection to provide an antireflection effect with respect to external light. The optical film having a haze of 0.3% or less can further improve the above effects. As described below, the optical film according to one or more embodiments of the present invention includes oblique stretching or MD stretching in the course of forming the second layer after formation of the first primer layer. The first primer layer having a glass transition temperature within the above range enables efficient formation of the first layer and the second layer, which have phase retardation according to the present invention. In an embodiment, the optical film may have a haze of 0%, 0.05%, 0.1%, 0.15%, 0.2%, 0.25%, or 0.3%, for example, 0% to 0.3%.

In the optical film according to one or more embodiments of the present invention, each of the first primer layer and the second primer layer has a glass transition temperature of 50° C. to 100° C. and is a (meth)acrylate based primer layer, whereby the optical film including the first layer, the second layer, and the third layer each having a glass transition temperature and modulus described below can improve durability after dipping in hot water, heat resistance durability, and humid-heat resistance durability. In an embodiment, the first layer has a lower glass transition temperature and a higher modulus than each of the second layer and the third layer.

When applied to a polarizing plate, the optical film according to the present invention can improve heat resistance durability and humid-heat resistance durability of the polarizing plate. It is believed that this result is obtained mainly through chemical and physical bonding between a phase retardation resin and a primer layer while securing good peel strength to improve reliability by application of a primer layer having a relatively high glass transition temperature so as to suppress interlayer distortion at high temperature. However, it is to be understood that the present invention is not limited thereto.

In an embodiment, the optical film may have a peel strength of 300 gf/25 mm or more, for example, 300 gf/25 mm to 600 gf/25 mm, between the first layer and the second layer and a peel strength of 300 gf/25 mm or more, for example, 300 gf/25 mm to 600 gf/25 mm, between the first layer and the third layer. Here, “peel strength” may be measured by a method described below in examples.

In an embodiment, the first primer layer and the second primer layer may have the same glass transition temperature or different glass transition temperatures. In an embodiment, the first primer layer and the second primer layer have the same glass transition temperature, thereby enabling easy realization of the effects of the present invention.

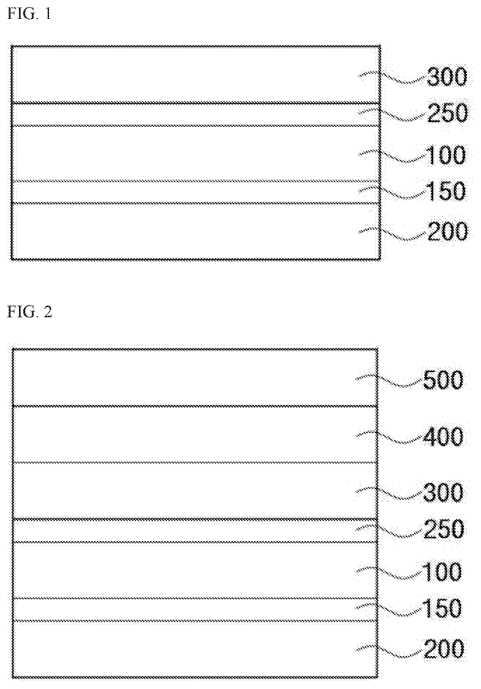

Herein, an optical film according to an embodiment of the present invention will be described in further detail with reference to FIG. 1.

Referring to FIG. 1, an optical film includes a third layer 300, a second primer layer 250, a first layer 100, a first primer layer 150, and a second layer 200, which are sequentially stacked in the stated order.

The first layer 100 and the third layer 300 may be closely connected to each other by the second primer layer 250, and the first layer 100 and the second layer 200 may be closely connected to each other by the first primer layer 150.

In an embodiment, only the second primer layer 250 may be present between the first layer 100 and the third layer 300 and only the first primer layer 150 may be present between the first layer 100 and the second layer 200.

### First Layer

The first layer 100 may be a layer exhibiting substantially no in-plane retardation. In an embodiment, the first layer 100 is a retardation layer and has in-plane retardation within a range (e.g., a predetermined range) such that the optical film can provide an antireflection function.

In an embodiment, the first layer 100 may have an in-plane retardation of 180 nm to 240 nm at a wavelength of 550 nm. As a result, the first layer 100 can achieve remarkable reduction in reflectivity at front and lateral sides while improving ellipticity at the lateral side when combined with the second layer 200 exhibiting in-plane retardation at a wavelength of 550 nm. In an embodiment, the first layer 100 may have an in-plane retardation of 180 nm, 185 nm, 190 nm, 195 nm, 200 nm, 205 nm, 210 nm, 215 nm, 220 nm, 225 nm, 230 nm, 235 nm, or 240 nm, and, in an embodiment, 180 nm to 235 nm, at a wavelength of 550 nm.

The first layer 100 exhibits positive dispersion and, in an embodiment, may have a short wavelength dispersion of 1 to 1.1 and a long wavelength dispersion of 0.96 to 1. Within this range, the optical film can reduce reflectivity at front and lateral sides while improving ellipticity, when used in a polarizing plate. In an embodiment, the first layer 100 has a short wavelength dispersion of 1.03 to 1 and a long wavelength dispersion of 0.98 to 1, and, in an embodiment, 0.99 to 1, and, in an embodiment, 0.995 to 1. In an embodiment, the first layer 100 may have an in-plane retardation of 180 nm to 280 nm, and, in an embodiment, 185 nm to 260 nm, and, in an embodiment, 190 nm to 250 nm, at a wavelength of 450 nm, and an in-plane retardation of 175 nm to 270 nm, and, in an embodiment, 180 nm to 255 nm, and, in an embodiment, 185 nm to 240 nm, at a wavelength of 650 nm. Within this range, the first layer 100 can achieve the short wavelength dispersion and the long wavelength dispersion within the above ranges.

In an embodiment, the first layer 100 may have an out-of-plane retardation of 80 nm to 250 nm, and, in an embodiment, 80 nm, 90 nm, 100 nm, 110 nm, 120 nm, 130 nm, 140 nm, 150 nm, 160 nm, 170 nm, 180 nm, 190 nm, 200 nm, 210 nm, 220 nm, 230 nm, 240 nm, or 250 nm, and, in an embodiment, 95 nm to 200 nm, and, in an embodiment, 105 nm to 180 nm, at a wavelength of 550 nm. Within this range, the first layer 100 can improve lateral reflectivity.

In an embodiment, the first layer 100 may have a degree of biaxiality of 1 to 1.5, and, in an embodiment, 1, 1.1, 1.2, 1.3, 1.4, or 1.5, and, in an embodiment, 1 to 1.3, and, in an embodiment, 1.1 to 1.3, at a wavelength of 550 nm. Within this range, the first layer 100 can improve lateral reflectivity.

The first layer 100 may have a thickness of 70 μm or less, for example, greater than 0 μm, 5 μm, 10 μm, 15 μm, 20 μm, 25 μm, 30 μm, 35 μm, 40 μm, 45 μm, 50 μm, 55 μm, 60 μm, 65 μm, or 70 μm, and, in an embodiment, 20 μm to 70 μm, and, in an embodiment, 20 μm to 50 μm. Within this range, the first layer 100 can be used in the optical film.

The first layer 100 may have a lower glass transition temperature than each of the second layer 200 and the third layer 300. In an embodiment, the first layer 100 may have a glass transition temperature of 100° C. to 150° C., and, in an embodiment, 100° C., 105° C., 110° C., 115° C., 120° C., 125° C., 130° C., 135° C., 140° C., 145° C., or 150° C., and, in an embodiment, 120° C. to 140° C. Within this range, the optical film can realize target retardation without fracture upon stretching in the course of forming the first layer 100 and the second layer 200.

The first layer 100 may have higher modulus than each of the second layer 200 and the third layer 300. In an embodiment, the first layer 100 may have a modulus of 1 GPa to 10 GPa, and, in an embodiment, 1 GPa, 2 GPa, 3 GPa, 4 GPa, 5 GPa, 6 GPa, 7 GPa, 8 GPa, 9 GPa, or 10 GPa, for example, 2 GPa to 5 GPa. Within this range, the first layer 100 can further improve reliability through combination with the primer layers according to the present invention.

The first layer 100 is a non-liquid crystal film or a liquid crystalline film. In an embodiment, the first layer 100 includes a stretched non-liquid film formed of an optically transparent resin. The “non-liquid crystal film” may mean a film that is not formed of at least one of a liquid crystal monomer, a liquid crystal oligomer, and a liquid crystal polymer or is formed of a material that is not converted into a liquid crystal monomer, a liquid crystal oligomer, or a liquid crystal polymer by light irradiation.

For example, the first layer 100 may include at least one selected from among a cellulose based resin including triacetylcellulose and the like, a polyester based resin including polyethylene terephthalate (PET), polybutylene terephthalate, polyethylene naphthalate, polybutylene naphthalate, and the like, a cyclic olefin copolymer (COC) based resin, a cyclic olefin polymer (COP) based resin, a polycarbonate based resin, a polyethersulfone based resin, a polysulfone based resin, a polyamide based resin, a polyimide based resin, a polyolefin based resin, a polyarylate based resin, a polyvinyl alcohol based resin, a polyvinyl chloride based resin, and a polyvinylidene chloride based resin. In an embodiment, the first layer 100 includes a cyclic olefin polymer (COP) based film in order to secure the short wavelength dispersion and the long wavelength dispersion within the above range. The cyclic olefin polymer based film can provide advantageous effects of improvement in front reflectivity in the polarizing plate according to the present invention and can secure good peel strength when applied to the first primer layer 150 and the second primer layer 250.

The first layer 100 may be a hydrophobic film. For example, the hydrophobic film may include a cyclic olefin polymer (COP) based film and/or a cyclic olefin copolymer (COC) based film. In an embodiment, the first layer 100 may include a film formed of a resin having positive (+) inherent birefringence.

The first layer 100 may have the aforementioned retardation by forming the first primer layer 150 on a non-stretched or partially stretched film for the first layer 100 and forming a coating for a coating layer, followed by concurrently (e.g., simultaneously) stretching a laminate of the non-stretched or partially stretched film, the first primer layer 150 and the coating for the coating layer. In an embodiment, the first layer 100 is formed by the latter process in order to secure the effects of the present invention. This will be described below in further detail.

### Second Layer

The second layer 200 is formed on a lower surface of the first primer layer 150. Although the second layer 200 may be a layer exhibiting substantially no in-plane retardation, in an embodiment, the second layer 200 has an in-plane retardation of 70 nm to 120 nm at a wavelength of 550 nm to provide an antireflection function. As a result, the second layer 200 can achieve remarkable reduction in reflectivity at front and lateral sides while improving ellipticity at the lateral side when combined with the first layer 100. In an embodiment, the second layer 200 may have an in-plane retardation of 70 nm, 75 nm, 80 nm, 85 nm, 90 nm, 95 nm, 100 nm, 105 nm, 110 nm, 115 nm, or 120 nm, and, in an embodiment, 80 nm to 115 nm, and, in an embodiment, 80 nm to 110 nm, at a wavelength of 550 nm.

The second layer 200 exhibits positive dispersion and, in an embodiment, may have a short wavelength dispersion of 1 to 1.15 and a long wavelength dispersion of 0.94 to 1. Within this range, the second layer 200 can improve ellipticity at each wavelength through reduction in wavelength dispersion, as compared to the first layer 100, thereby improving reflectivity. In an embodiment, the second layer 200 has a short wavelength dispersion of 1 to 1.06 and a long wavelength dispersion of 0.97 to 1. In an embodiment, the second layer 200 may have an in-plane retardation of 80 nm to 120 nm, and, in an embodiment, 85 nm to 115 nm, and, in an embodiment, 90 nm to 110 nm, at a wavelength of 450 nm, and an in-plane retardation of 80 nm to 110 nm, and, in an embodiment, 85 nm to 105 nm, at a wavelength of 650 nm. Within this range, the second layer 200 can easily achieve the short wavelength dispersion and the long wavelength dispersion within the above ranges.

In an embodiment, the second layer 200 may have an out-of-plane retardation of −250 nm to −50 nm, and, in an embodiment, −250 nm, −240 nm, −230 nm, −220 nm, −210 nm, −200 nm, −190 nm, −180 nm, −170 nm, −160 nm, −150 nm, −140 nm, −130 nm, −120 nm, −110 nm, −100 nm, −90 nm, −80 nm, −70 nm, −60 nm, or −50 nm, and, in an embodiment, −150 nm to −60 nm, at a wavelength of 550 nm. Within this range, the second layer 200 can improve lateral reflectivity through improvement in ellipticity at the lateral side.

In an embodiment, the second layer 200 may have a biaxiality of −2 to −0.1, and, in an embodiment, −2, −1.9, −1.8, −1.7, −1.6, −1.5, −1.4, −1.3, −1.2, −1.1, −1.0, −0.9, −0.8, −0.7, −0.6, −0.5, −0.4, −0.3, −0.2, or −0.1, and, in an embodiment, −1.5 to −0.1, and, in an embodiment, −0.5 to −0.1, at a wavelength of 550 nm. Within this range, the second layer 200 can improve lateral reflectivity through improvement in ellipticity at the lateral side.

The second layer 200 may have a total light transmittance of 90% or more, for example, 90% to 100%, and a haze of 2% or less, for example, 0% to 2%, or higher than 0.5% to 2%. Within this range, the second layer 200 can be used in the optical film.

The second layer 200 may have a thickness of greater than 0 μm to 10 μm, and, in an embodiment, greater than 0 μm, 1 μm, 2 μm, 3 μm, 4 μm, 5 μm, 6 μm, 7 μm, 8 μm, 9 μm, or 10 μm, for example, 1 μm to 10 μm, and, in an embodiment, 2 μm to 8 μm. Within this range, the optical film can achieve thickness reduction.

In an embodiment, the second layer 200 has a lower index of refraction than the first layer 100 and may have an index of refraction of 1 to 2, and, in an embodiment, 1.4 to 1.6, and, in an embodiment, 1.5 to 1.6. Within this range, the second layer 200 can assist in reduction of haze of the optical film while improving transparency of the optical film through control of the index of refraction with respect to the first layer 100.

The second layer 200 may have a higher glass transition temperature than the first layer 100. In an embodiment, the second layer 200 may have a glass transition temperature of 200° C. to 300° C., and, in an embodiment, 200° C., 210° C., 220° C., 230° C., 240° C., 250° C., 260° C., 270° C., 280° C., 290° C., or 300° C., and, in an embodiment, 220° C. to 280° C., and, in an embodiment, 240° C. to 250° C. Within this range, the second layer 200 can secure reliability of the optical film at high temperature and/or humidity.

In an embodiment, the second layer 200 may have a modulus of 1 GPa to 10 GPa, and, in an embodiment, 1 GPa, 2 GPa, 3 GPa, 4 GPa, 5 GPa, 6 GPa, 7 GPa, 8 GPa, 9 GPa, or 10 GPa, for example, 2 GPa to 5 GPa. Within this range, the second layer 200 can further improve reliability through combination with the primer layers according to the present invention.

The second layer 200 may be formed of a different material than the first layer 100 and has different birefringence than the first layer 100. The second layer 200 may be formed of a material having negative (−) inherent birefringence.

The second layer 200 is a non-liquid crystal retardation layer and may include a polystyrene based polymer and/or a cellulose based polymer as a main component. According to the present invention, in consideration of the above retardation and wavelength dispersion, while securing good peel strength with respect to the first primer layer 150, the second layer 200, in an embodiment, is formed of a composition comprising a halogen-containing polystyrene based polymer and/or a halogen-containing cellulose based polymer. In an embodiment, the halogen is fluorine. Herein, “polymer” includes an oligomer, a polymer, or a resin. Herein, “main component” means a component that is present in an amount of 95 wt % or more, e.g., 95 wt % to 99 wt %, in the second layer 200.

The halogen-containing polystyrene based polymer may include a repeat unit represented by the following Formula 1:

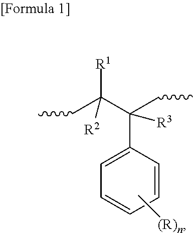

where

[symbol]

is a linking site; R¹, R², and R³ are each independently a hydrogen atom, an alkyl group, a substituted alkyl group, or a halogen; Rs are each independently an alkyl group, a substituted alkyl group, a halogen, a hydroxyl group, a carboxyl group, a nitro group, an alkoxy group, an amino group, a sulfonate group, a phosphate group, an acyl group, an acyloxy group, a phenyl group, an alkoxy carbonyl group, or a cyano group, at least one of R¹, R², and R³ being a halogen and/or at least one R being a halogen; and n is an integer of 0 to 5.

In an embodiment, the halogen means fluorine (F), Cl, Br, or I, and, in an embodiment, F.

The halogen-containing polystyrene based polymer may be formed through polymerization of, for example, a mixture containing 1-(2,2-difluoroethenyl)-2-fluorobenzene and/or 1′,2′,2′-trifluorostyrene. The mixture may further include styrene.

The cellulose based polymer may include at least a unit in which at least some hydroxyl groups [a C₂ hydroxyl group, a C₃ hydroxyl group, or a C₆ hydroxyl group] of a sugar monomer constituting cellulose are substituted with an acyl group or an ether group. That is, the cellulose based polymer may include a cellulose ester polymer and/or a cellulose ether polymer.

For example, the cellulose based polymer may include a cellulose ester polymer having a unit in which at least some hydroxyl groups [a C₂ hydroxyl group, a C₃ hydroxyl group or a C₆ hydroxyl group] of a sugar monomer constituting cellulose are substituted with an acyl group, as represented by the following Formula 2. Here, the acyl group may be substituted or unsubstituted.

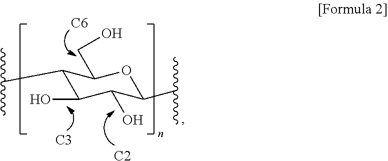

where n is an integer of 1 or more.

A substituent group for the cellulose ester or acyl group may include at least one selected from among a halogen atom, a nitro group, an alkyl group (for example, a C₁ to C₂₀ alkyl group), an alkenyl group (for example, a C₂ to C₂₀ alkenyl group), a cycloalkyl group (for example, a C₃ to C₁₀ cycloalkyl group), an aryl group (for example, a C₆ to C₂₀ aryl group), a hetero-aryl group (for example, a C₃ to C₁₀ aryl group), an alkoxy group (for example, a C₁ to C₂₀ alkoxy group), an acyl group, and a halogen-containing functional group. The substituent groups may be the same as or different from each other.

Herein, “acyl” may mean R—C(═O)—* (* being a linking site, R being a C₁ to C₂₀ alkyl group, a C₃ to C₂₀ cycloalkyl group, a C₆ to C₂₀ aryl group, or a C₇ to C₂₀ arylalkyl group), as well-known in the art. The “acyl” is coupled to a ring of the cellulose through ester bonding (through an oxygen atom) in the cellulose.

Here, “alkyl,” “alkenyl,” “cycloalkyl,” “aryl,” “hetero-aryl,” “alkoxy,” and “acyl” refer to non-halogen compounds for convenience. The second retardation layer composition may include the cellulose ester polymer alone or a mixture including the cellulose ester polymer.

Here, “halogen” means fluorine (F), Cl, Br, or I, and, in an embodiment, F.

The “halogen-containing functional group” is an organic functional group containing at least one halogen atom and may include an aromatic, aliphatic or alicyclic functional group. For example, the halogen-containing functional group may mean a halogen-substituted C₁ to C₂₀ alkyl group, a halogen-substituted C₂ to C₂₀ alkenyl group, a halogen-substituted C₂ to C₂₀ alkynyl group, a halogen-substituted C₃ to C₁₀ cycloalkyl group, a halogen-substituted C₁ to C₂₀ alkoxy group, a halogen-substituted acyl group, a halogen-substituted C₆ to C₂₀ aryl group, or a halogen-substituted C₇ to C₂₀ arylalkyl group, without being limited thereto.

The “halogen-substituted acyl group” may be R′—C(═O)—* (* being a linking site, R′ being a halogen-substituted C₁ to C₂₀ alkyl group, a halogen-substituted C₃ to C₂₀ cycloalkyl group, a halogen-substituted C₆ to C₂₀ aryl group, or a halogen-substituted C₇ to C₂₀ arylalkyl group). The “halogen-substituted acyl group” may be coupled to a ring of the cellulose through ester bonding (through an oxygen atom) in the cellulose.

The cellulose ester based polymer may be prepared by a typical method known to those skilled in the art or may be obtained from commercially available products. For example, the cellulose ester based polymer having an acyl group as a substituent group may be prepared by reacting trifluoroacetic acid or trifluoroacetic anhydride with the sugar monomer constituting the cellulose represented by Formula 2 or a polymer of the sugar monomer, by reacting trifluoroacetic acid or trifluoroacetic anhydride therewith, followed by additionally reacting an acylation agent (for example, carboxylic anhydride or carboxylic acid) therewith, or by reacting both the acylation agent and trifluoroacetic acid or trifluoroacetic anhydride therewith.

The second retardation layer composition may further include typical additives known to those skilled in the art. The additives may include any of a wavelength dispersion regulator (for example, an aromatic fused ring-containing compound including 2-naphthylbenzoate, anthracene, phenanthrene, 2,6-naphthalene dicarboxylic acid diester, and the like), a pigment, an antioxidant, an antistatic agent, and a heat stabilizer, without being limited thereto.

The second layer 200 is a stretched coating layer. This will be described in detail in a method of forming an optical film.

### Third Layer

The third layer 300 can further improve lateral reflectivity. Although the third layer 300 may be a layer exhibiting substantially no in-plane retardation, in an embodiment, the third layer may include a positive (+) C layer satisfying a relation: nz>nx≈ny (nx, ny, and nz being the indexes of refraction of the third layer 300 in the slow axis direction, the fast axis direction, and the thickness direction thereof at a wavelength of 550 nm, respectively).

In an embodiment, the third layer 300 may have an out-of-plane retardation of −300 nm to 0 nm, for example, −200 nm to −10 nm, at a wavelength of 550 nm. In an embodiment, the third layer 300 may have an in-plane retardation of 0 nm to 10 nm, for example, 0 nm to 5 nm, at a wavelength of 550 nm. Within this range, the third layer 300 can realize the aforementioned effect of reducing front reflectivity.

The third layer 300 may have a higher glass transition temperature than the first layer 100. In an embodiment, the third layer 300 may have a glass transition temperature of 200° C. to 300° C., and, in an embodiment, 220° C. to 280° C., and, in an embodiment, 240° C. to 250° C. Within this range, the third layer 300 does not suffer from deformation at high temperature to provide an advantageous effect in peel strength reliability at high temperature.

In an embodiment, the third layer 300 may have a modulus of 1 GPa to 10 GPa, for example, 2 GPa to 5 GPa. Within this range, the third layer 300 can further improve reliability through combination with the primer layers according to the present invention.

The third layer 300 is a non-liquid crystal retardation layer and may be formed of the same material as the second layer 200. The third layer 300 may include a polystyrene based polymer and/or a cellulose based polymer, which have a repeat unit of Formula 1 or 2, to secure good peel strength with respect to the second primer layer 250. For example, the third layer 300 may be formed of a composition comprising a halogen-containing polystyrene polymer and/or a halogen-containing cellulose polymer. In an embodiment, the halogen is fluorine.

In an embodiment, the fluorine-containing polystyrene based polymer may be prepared by polymerizing a mixture including 1-(2,2-difluoroethenyl)-2-fluorobenzene and/or 1′,2′,2′-trifluorostyrene. The mixture may further include styrene.

The third layer 300 may have a thickness of greater than 0 μm to 10 μm, for example, 1 μm to 5 μm, and, in an embodiment, 1 μm to 2 μm. Within this range, the optical film can achieve thickness reduction.

The third layer 300 is a non-stretched coating layer. This will be described in further detail in a method of forming an optical film.

### First Primer Layer and Second Primer Layer

In an embodiment, each of the first primer layer 150 and the second primer layer 250 has a glass transition temperature of 50° C. to 100° C. and is a (meth)acrylate based primer layer.

According to the present invention, the first primer layer 150 disposed between the first layer 100 and the second layer 200 and the second primer layer 250 disposed between the first layer 100 and the third layer 300 have particular glass transition temperatures and are formed of particular materials. As a result, the optical film can realize retardation of each of the first layer 100 and the second layer 200 without separation between the first layer 100 and the second layer 200 upon stretching at high temperature, and can secure high reliability by preventing or substantially preventing interlayer peeling through reduction in stress variation between the first layer 100, the second layer 200, and the third layer 300 each having the glass transition temperature and the modulus within the above ranges upon evaluation of durability, heat resistance durability, and humid-heat resistance durability through immersion testing in hot water. Further, a polarizing plate adopting the optical film has good properties in terms of heat resistance durability and humid-heat resistance durability, and does not suffer from a problem of breakage of the primer layers due to embrittlement of the primer layers in each of the optical film and the polarizing plate.

If each of the first primer layer and the second primer layer has a glass transition temperature of less than 50° C., the optical film and the polarizing plate can suffer from deterioration in reliability and durability, and if each of the first primer layer and the second primer layer has a glass transition temperature of greater than 100° C., there can be problem of breakage of the primer layers due to embrittlement of the primer layers. When the primer layer other than a (meth)acrylate resin has a glass transition temperature of 50° C. to 100° C., there can be problems of poor properties in terms of durability, heat resistance durability, and humid-heat resistance durability or a problem of deterioration in reliability of the polarizing plate.

In an embodiment, each of the first primer layer 150 and the second primer layer 250 has a glass transition temperature of 50° C., 55° C., 60° C., 65° C., 70° C., 75° C., 80° C., 85° C., 90° C., 95° C., or 100° C., and, in an embodiment, 60° C. to 100° C.

The first primer layer 150 and the second primer layer 250 may have the same glass transition temperature or different glass transition temperatures. In an embodiment, a difference in glass transition temperature between the first primer layer 150 and the second primer layer 250 may be in the range of 0° C. to 10° C., and, in an embodiment, 0° C., 1° C., 2° C., 3° C., 4° C., 5° C., 6° C., 7° C., 8° C., 9° C., or 10° C., and, in an embodiment, 0° C. to 5° C. Within this range, the polarizing plate can be manufactured with good processability.

In an embodiment, each of the first primer layer 150 and the second primer layer 250 may have lower modulus than each of the first layer 100, the second layer 200, and the third layer 300. As a result, the optical film or the polarizing plate can have improvement in durability, heat resistance durability, and humid-heat resistance durability upon dipping testing in hot water. In an embodiment, each of the first primer layer 150 and the second primer layer 250 may have a modulus of 0.1 GPa to 5 GPa, and, in an embodiment, 0.1 GPa to 3 GPa.

Each of the first primer layer 150 and the second primer layer 250 may be formed of a (meth)acrylate based primer layer composition. The glass transition temperature of each of the first primer layer 150 and the second primer layer 250 may be realized through adjustment of the kind of monomer and/or the content thereof and weight average molecular weights thereof in a (meth)acrylate based copolymer in the primer layer composition.

The primer layer composition may include a (meth)acrylate copolymer as a main component and may realize a glass transition temperature of 50° C. to 100° C. after curing. Here, “main component” means a component present in an amount of 95 wt % or more, e.g., 95 wt % to 99 wt % in each of the first primer layer 150 and the second primer layer 250.

The (meth)acrylate copolymer may be a copolymer of a monomer mixture including a (meth)acrylic monomer having have a glass transition temperature of 10° C. to 100° C., and, in an embodiment, 50° C. to 80° C., and, in an embodiment, 60° C. to 70° C. in a homopolymer phase. Within this range, the glass transition temperatures of the primer layers can be easily realized. Here, “glass transition temperature in a homopolymer phase” may be measured by a typical method known to those skilled in the art or may be obtained with reference to commercially available catalogues.

The (meth)acrylic monomer may include at least one selected from among methyl methacrylate, butyl acrylate, hydroxyethyl methacrylate, cyclohexyl methacrylate, and 2-ethylhexyl acrylate. For example, the (meth)acrylic monomer may be an alkyl group-containing (meth)acrylic ester, for example, a C₁ to C₁₀ alkyl group-containing (meth)acrylic ester, which can improve adhesion between the first layer and the second layer each exhibiting hydrophobic properties.

The monomer mixture may further include a peel strength-enhancing compound, which can improve interlayer peel strength, in addition to a monomer having a glass transition temperature of 10° C. to 100° C. in a homopolymer phase.

A modified (meth)acrylate copolymer may be prepared through polymerization of the peel strength-enhancing compound together with the monomer having a glass transition temperature of 10° C. to 100° C. in a homopolymer phase or through modification of a sidechain of a homopolymer of the monomer having a glass transition temperature of 10° C. to 100° C., thereby improving interlayer peel strength of each primer layer. Upon polymerization of the peel strength-enhancing compound together with the monomer having a glass transition temperature of 10° C. to 100° C. in a homopolymer phase, modified (meth)acrylic copolymer may be a random copolymer, a block copolymer, an alternating copolymer, or a graft copolymer, and, in an embodiment, a block copolymer, of the monomer having a glass transition temperature of 10° C. to 100° C. in a homopolymer phase and the peel strength-enhancing compound.

The peel strength-enhancing compound may include a (meth)acrylate based compound and/or an ester based compound.

The (meth)acrylate compound may include at least one selected from the group consisting of an alkyl (meth)acrylate, a cycloalkyl (meth)acrylate, and a non-cycloalkyl (meth)acrylate. Here, “alkyl” may be a C₁ to C₁₀ alkyl group, “cycloalkyl” may be a C₃ to C₁₀ cycloalkyl group, and “non-cycloalkyl” may be a C₅ to C₂₀ non-cycloalkyl group. For example, the (meth)acrylate compound may include at least one mono-ester compound of a (meth)acrylic acid, such as methyl (meth)acrylate, ethyl (meth)acrylate, n-propyl (meth)acrylate, iso-propyl (meth)acrylate, n-butyl (meth)acrylate, iso-butyl (meth)acrylate, t-butyl (meth)acrylate, n-hexyl (meth)acrylate, 2-ethylhexyl (meth)acrylate, isobornyl (meth)acrylate, cyclohexyl (meth)acrylate, n-octyl (meth)acrylate, n-hexyl (meth)acrylate, lauryl (meth)acrylate, and stearyl (meth)acrylate, with a C₁ to C₂₀ mono-alcohol, without being limited thereto.

The ester compound may be selected from formate based, acetate based, or (meth)acrylate based ester compounds, such as butyl acetic ester, butyl formic ester, 2-methyl-2-propenoic acid cyclohexyl ester, 2-propenoic acid 2-methyl-cyclohexyl ester, and isopropyl acetate, to improve peel strength.

Other monomers for the monomer mixture may include at least one compound having a polymerizable unsaturated bond selected from among, for example, an amide group-containing monomer, such as (meth)acrylamide, a carboxyl group-containing monomer, such as maleic acid, and the like; an epoxy group-containing monomer, such as (meth)acryl glycidyl and the like; acrylonitrile, styrene, vinyl acetate, vinyl chloride, and the like, other than a hydroxyl group-containing monomer and an alkyl (meth)acrylic ester monomer.

The peel strength-enhancing compound may be present in an amount of 1 part by weight to 10 parts by weight, for example, 5 parts by weight to 10 parts by weight, relative to 100 parts by weight of the monomer mixture. Within this range, the peel strength-enhancing compound can improve interlayer peel strength through increase in interlayer adhesion without affecting the glass transition temperatures of the primer layers.

Each of the (meth)acrylic copolymer and the modified (meth)acrylic copolymer may be prepared by a typical polymerization method well-known to those skilled in the art.

The primer layer composition may further include at least one selected from among the peel strength-enhancing compound and a curing agent.

The peel strength-enhancing compound may include the peel strength-enhancing compound described above. The peel strength-enhancing compound may be optionally present in an amount of 0 parts by weight to 10 parts by weight, for example, higher than 0 parts by weight to 5 parts by weight, relative to 100 parts by weight of the (meth)acrylate copolymer or the modified (meth)acrylate copolymer. Within this range, the peel strength-enhancing compound can improve interlayer peel strength through increase in interlayer adhesion without affecting the glass transition temperatures of the primer layers.

The curing agent can further improve peel strength of the primer layers by curing the (meth)acrylate copolymer or the modified (meth)acrylate copolymer. The curing agent may be suitably selected depending upon the kind of monomer contained in each of the (meth)acrylate copolymer or the modified (meth)acrylate copolymer. For example, the curing agent may include an isocyanate curing agent as a heat curing agent. The isocyanate curing agent may include hexamethylene diisocyanate and/or octamethylene diisocyanate.

The curing agent may be optionally present in an amount of 0 parts by weight to 10 parts by weight, and, in an embodiment, 0, 0.1, 0.5, 1, 1.5, 2, 2.5, 3, 3.5, 4, 4.5, 5, 5.5, 6, 6.5, 7, 7.5, 8, 8.5, 9, 9.5, or 10 parts by weight, for example, greater than 0 parts by weight to 5 parts by weight, and, in an embodiment, 0.1 parts by weight to 3 parts by weight, relative to 100 parts by weight of the (meth)acrylate copolymer or the modified (meth)acrylate copolymer. Within this range, the curing agent can improve interlayer peel strength through increase in interlayer adhesion without affecting the glass transition temperatures of the primer layers.

The primer layer composition may further include a solvent. An organic solvent can provide poor properties in terms of haze and compatibility by melting the first layer and the second layer or by melting the first primer layer due to remaining organic solvent, whereas a water-based solvent does not suffer from such problems. The water-based solvent may be water including ultrapure water, without being limited thereto. The water-based solvent may be present in the balance amount in the composition. According to the present invention, the primer layer composition contains the water-based solvent and increases peel strength between the first layer and the second layer without increase in haze by improving compatibility between the first layer and the second layer.

The primer layer composition may further include typical additives known to those skilled in the art.

Each of the primer layers may be formed by coating the primer layer composition to a thickness (e.g., a predetermined thickness) on the first layer, followed by photocuring and/or heat curing.

The first primer layer 150 and the second primer layer 250 may have the same thickness or different thicknesses, and may have a thickness of greater than 0 nm to 1,000 nm, and, in an embodiment, 1 nm, 5 nm, 50 nm, 100 nm, 150 nm, 200 nm, 250 nm, 300 nm, 350 nm, 400 nm, 450 nm, 500 nm, 550 nm, 600 nm, 650 nm, 700 nm, 750 nm, 800 nm, 850 nm, 900 nm, 950 nm, or 1,000 nm, for example, 100 nm to 500 nm, and, in an embodiment, 200 nm to 400 nm. Within this range, the optical film can further improve interlayer reliability.

Next, a method of manufacturing an optical film according to an embodiment will be described.

The optical film according to an embodiment of the present invention may be manufactured by forming a first primer layer on a non-stretched or partially stretched film for the first layer, coating a second layer composition on the first primer layer to form a coating for the second layer, stretching the entirety of the film, the first primer layer, and the coating for the second layer, and forming a second primer layer on an upper surface of the film, followed by coating a third layer composition on an upper surface of the second primer layer to form a coating for the third layer.

Stretching may be performed by stretching the entirety of the film, the first primer layer, and the coating for the second layer to 1.1 times to 1.8 times an initial length thereof, and, in an embodiment, 1.1 times to 1.5 times, and, in an embodiment, 1.1 times to 1.3 times, and, in an embodiment, at 110° C. to 150° C. Stretching may be performed by uniaxially or bi-axially stretching the entirety of the film, the first primer layer and the coating for the second layer in the machine direction (MD) or the oblique direction of the film.

Stretching may be performed by dry stretching or wet stretching. In an embodiment, dry stretching is performed to reduce variation in properties of a base film and a coating layer.

### Polarizing Plate

A polarizing plate according to the present invention includes a polarizer and the optical film according to an embodiment of the present invention on at least one surface of the polarizer.

Next, a polarizing plate according to an embodiment of the present invention will be described with reference to FIG. 2.

Referring to FIG. 2, a polarizing plate according to an embodiment includes a protective layer 500, a polarizer 400, and an optical film, which includes a third layer 300, a second primer layer 250, a first layer 100, a first primer layer 150, and a second layer 200 sequentially stacked in the stated order from the polarizer 400.

The third layer 300, the second primer layer 250, the first layer 100, the first primer layer 150, and the second layer 200 may be substantially the same as those of the optical film described above.

The polarizer 400 may convert natural light or polarized light into linearly polarized light through linear polarization in a certain direction. In an embodiment, the polarizer may have a thickness of 2 μm to 30 μm, and, in an embodiment, 4 μm to 25 μm. Within this range, the polarizer 400 can be used in the polarizing plate.

The polarizer 400 may be fabricated from a polymer film mainly consisting of a polyvinyl alcohol resin.

The protective layer 500 protects the polarizer 400 from an external environment while improving mechanical strength of the polarizing plate.

The protective layer 500 may include an optically transparent protective coating layer and/or an optically transparent protective film. The protective coating layer may include a coating layer formed of a composition containing an actinic radiation curable compound. The protective film is an optically transparent film and may include a film formed of at least one selected from among, for example, cellulose resins including triacetylcellulose (TAC) and the like, polyester resins including polyethylene terephthalate (PET), polybutylene terephthalate, polyethylene naphthalate, polybutylene naphthalate, and the like, cyclic olefin polymer resins, polycarbonate resins, polyether sulfone resins, polysulfone resins, polyamide resins, polyimide resins, polyolefin resins, polyarylate resins, polyvinyl alcohol resins, polyvinyl chloride resins, and polyvinylidene chloride resins. In an embodiment, the protective film may be a TAC film or a PET film. The protective layer may have a thickness of 0.1 μm to 100 μm, and, in an embodiment, 5 μm to 70 μm, and, in an embodiment, 15 μm to 45 μm. Within this range, the protective film can be used in the polarizing plate. The protective layer may be omitted from the polarizing plate so long as the polarizing plate provides inherent functions thereof. Although not shown in FIG. 2, in an embodiment, the protective layer 500 may be bonded to the polarizer 400 by a bonding layer. The bonding layer may be formed of a photocurable bonding agent and/or a water-based bonding agent, but is not limited thereto.

### Optical Display Apparatus

An optical display apparatus according to the present invention may include the optical film and/or the polarizing plate according to the present invention. In an embodiment, the optical display apparatus may include any of an organic light emitting diode (OLED) display and a liquid crystal display.

In an embodiment, the OLED display apparatus may include: an OLED panel including a flexible substrate; and the polarizing plate according to an embodiment of the present invention stacked on the OLED panel.

In another embodiment, the OLED display apparatus may include: an OLED panel including a non-flexible substrate; and the polarizing plate according to an embodiment of the present invention stacked on the OLED panel.

Next, the present invention will be described in further detail with reference to some examples. However, it is to be understood that these examples are provided for illustration and should not be construed in any way as limiting the invention.

### EXAMPLE 1

A (meth)acrylic copolymer was prepared through polymerization of a monomer mixture comprising a methyl methacrylate (glass transition temperature in homopolymer phase: 60° C.) alone. Each of first and second primer layer compositions was prepared by mixing 100 parts by weight of the (meth)acrylic copolymer with 1 part by weight of hexamethylene diisocyanate (HDI) as a curing agent.

A first primer layer was formed by depositing the first primer layer composition to a predetermined thickness on a lower surface of a cyclic olefin polymer (COP) film (ZD film, Zeon Co., Ltd.), which was obliquely stretched in a direction of 45° with reference to the MD, followed by drying and curing.

A coating for a second layer was formed by depositing a second layer composition (containing a fluorine-containing polystyrene based polymer, VM500, EASTMAN) on a lower surface of the first primer layer, followed by drying.

The first primer layer (thickness: 200 nm) and the second layer (positive dispersion, thickness: 5 μm) were sequentially formed on a lower surface of a first layer (positive dispersion, thickness: 40 μm) by obliquely stretching a laminate of the COP film, the first primer layer, and the coating to 1.3 times an initial length thereof in a direction of 0° with reference to the MD of the COP film at 130° C.

A second primer layer was formed by depositing the second primer layer composition on an upper surface of the first layer, followed by drying and curing. A third layer composition (containing a fluorine-containing polystyrene based polymer, VM500, EASTMAN) was deposited onto an upper surface of the second primer layer and dried thereon, thereby preparing an optical film in which a third layer (+C, Rth @ 550 nm: −60 nm, positive dispersion, thickness: 2 μm, Tg: 240 to 250° C., modulus: 2 GPa), the second primer layer (thickness: 200 nm, modulus: 0.5 GPa), the first layer (Re @ 550 nm: 225 nm, NZ: 1.16, positive dispersion, thickness: 40 μm, Tg: 120 to 140° C., modulus: 3 GPa), the first primer layer (thickness: 200 nm, modulus: 0.5 GPa), and the second layer (Re @ 550 nm: 110 nm, NZ: −0.30, positive dispersion, thickness: 5 μm, Tg: 240 to 250° C., modulus: 2 GPa) are sequentially stacked in the stated order.

A polarizer (thickness: 13 μm, light transmittance: 44%) was prepared by stretching a polyvinyl alcohol film to 3 times an initial length thereof at 60° C., dyeing the polyvinyl alcohol film with iodine, and stretching the dyed polyvinyl alcohol film to 2.5 times in an aqueous solution of boric acid at 40° C.

A polarizing plate was prepared by bonding the prepared optical film to a lower surface of the polarizer while bonding a triacetylcellulose film to an upper surface of the polarizer using a photocurable bonding agent.

### EXAMPLE 2

An optical film and a polarizing plate were prepared in the same manner as in Example 1 except that a composition containing a cellulose ester polymer (VM512, EASTMAN) was used as the second layer composition instead of the composition containing the fluorine-containing polystyrene based polymer.

### EXAMPLE 3

A modified (meth)acrylic copolymer (block copolymer of methyl methacrylate and 2-methyl-2-propenoic acid cyclohexyl ester) was prepared through polymerization of 100 parts by weight of a monomer mixture comprising 90 parts by weight of methyl methacrylate (glass transition temperature in homopolymer phase: 60° C.) and 10 parts by weight of 2-methyl-2-propenoic acid cyclohexyl ester. Each of first and second primer layer compositions was prepared by mixing 100 parts by weight of the (meth)acrylic copolymer with 1 part by weight of hexamethylene diisocyanate as a curing agent. An optical film and a polarizing plate were prepared in the same manner as in Example 1 except that the prepared first primer layer composition and the prepared second primer layer composition were used.

### EXAMPLE 4

A modified (meth)acrylic copolymer (block copolymer of methyl methacrylate and butyl acetic ester) was prepared through polymerization of 100 parts by weight of a monomer mixture comprising 95 parts by weight of methyl methacrylate (glass transition temperature in homopolymer phase: 60° C.) and 5 parts by weight of butyl acetic ester. Each of first and second primer layer compositions was prepared by mixing 100 parts by weight of the (meth)acrylic copolymer with 1 part by weight of hexamethylene diisocyanate as a curing agent. An optical film and a polarizing plate were prepared in the same manner as in Example 1 except that the prepared first primer layer composition and the prepared second primer layer composition were used.

### EXAMPLE 5

A modified (meth)acrylic copolymer was prepared through polymerization of 100 parts by weight of a monomer mixture comprising 90 parts by weight of methyl methacrylate (glass transition temperature in homopolymer phase: 60° C.) and 10 parts by weight of butyl formic ester. Each of first and second primer layer compositions was prepared by mixing 100 parts by weight of the (meth)acrylic copolymer (block copolymer of methyl methacrylate and butyl formic ester) with 1 part by weight of hexamethylene diisocyanate as a curing agent. An optical film and a polarizing plate were prepared in the same manner as in Example 1 except that the prepared first primer layer composition and the prepared second primer layer composition were used.

### EXAMPLE 6

An optical film and a polarizing plate were prepared in the same manner as in Example 1 except that polymerization time and temperature were changed in preparation of the (meth)acrylic copolymer.

### Comparative Examples 1 to 8

An optical film and polarizing plates were prepared in the same manner as in Example 1 except that the first primer layer composition and the second primer layer composition were changed as listed in Table 1.

TABLE 1

| | Primer layer | | Curing agent | |
|---|---|---|---|---|
| | composition | Main component in primer layer | Kind | Content |
| Example | (Meth)acrylate based | Methyl methacrylate copolymer | HDI | 1 |
| 1 | | | | |
| Example | (Meth)acrylate based | Methyl methacrylate copolymer | HDI | 1 |
| 2 | | | | |
| Example | Modified (Meth) | Copolymer of methyl methacrylate | HDI | 1 |
| 3 | acrylate based | and 2-methyl-2-propenoic acid | | |
| | | cyclohexyl ester | | |
| Example | Modified (Meth) | Copolymer of methyl methacrylate | HDI | 1 |
| 4 | acrylate based | and butyl acetic ester | | |
| Example | Modified (Meth) | Copolymer of methyl methacrylate | HDI | 1 |
| 5 | acrylate based | and butyl formic ester | | |
| Example | (Meth)acrylate based | Methyl methacrylate copolymer | HDI | 1 |
| 6 | | | | |
| Compara- | Ester based | — | — | — |
| tive Ex- | | | | |
| ample 1 | | | | |
| Compara- | Urethane based | Polyol and cyclohexylene | IPDI | 1 |
| tive Ex- | | diisocyanate | | |
| ample 2 | | | | |
| Compara- | Urethane based | Polyol and alicyclic isocyanate | IPDI | 1 |
| tive Ex- | | compound | | |
| ample 3 | | | | |
| Compara- | Urethane based | Polyol and cyclohexylene | IPDI | 1 |
| tive Ex- | | diisocyanate | | |
| ample 4 | | | | |
| Compara- | Urethane ester based | Copolymer of polyol, alicyclic | IPDI | 3 |
| tive Ex- | | isocyanate compound, and | | |
| ample 5 | | butyl acetic ester | | |
| Compara- | Urethane ester based | Copolymer of polyol, alicyclic | IPDI | 5 |
| tive Ex- | | isocyanate compound, and | | |
| ample 6 | | butyl acetic ester | | |
| Compara- | (Meth)acrylate | Copolymer of methyl methacrylate | HDI | 1 |
| tive Ex- | based | and butyl formic ester | | |
| ample 7 | | | | |
| Compara- | (Meth)acrylate based | Copolymer of methyl methacrylate | HDI | 1 |
| tive Ex- | | and butyl formic ester | | |
| ample 8 | | | | |

*In Table 1, Comparative Example 1 is Paraloid B-44 (Dow Inc.)

The optical films and the polarizing plates prepared in the Examples and Comparative Examples were evaluated as to the following properties, and results are shown in Table 2.

(1) Glass transition temperature of primer layer (unit: ° C.): Glass transition temperature Tg was measured with respect to a first primer layer (the same as a second primer layer) formed in the same manner as in each of the Examples and Comparative Examples by differential scanning calorimetry (DSC).

(2) Haze (unit: %) and light transmittance (unit: %) of optical film: Haze and light transmittance of an optical film were measured using a haze meter (Nippon Denshoku Co., Ltd.) at a wavelength of 380 nm to 780 nm.

(3) Peel strength between layers (unit: gf/25 mm): Each of the optical films was cut into a sample having a size of 25 mm×100 mm, which in turn was attached to an alkali-free glass plate via a pressure-sensitive adhesive using a laminator such that the second layer was attached to the glass plate. Next, the sample was compressed in an autoclave (at 50° C. and 5 atm) for 20 min and left under constant temperature and humidity conditions (23° C., 50% RH) for 4 hours. Thereafter, peel strength was measured using a peel strength tester (Texture analyzer, Stable Micro-System Inc., GB) at 25° C. under the conditions: a peeling rate of 300 mm/min and a peeling angle of 180°. With the first layer, that is, the COP film, secured to the peel strength tester by a clip of the peel strength tester, interlayer primer peel strength between the first layer and the second layer was measured while pulling the sample from the second layer at an angle of 180° under constant force.

(4) Cross-cut between layers: Adhesion was evaluated by a cross-cut method. Each of the optical films was cut into a square sample having a size of 10 mm×10 mm (length×width). Then, 10 longitudinal lines and 10 transverse lines were drawn on the sample, which in turn was cut to a depth of the first layer along the lines to divide the sample into a total of 100 pieces. An adhesive tape (General Consumables, Nichiban Co., Ltd.) was attached to the second layer, followed by counting the number of pieces remaining on the second layer upon peeling the adhesive tape off of the second layer. A greater number of pieces remaining on the second layer indicates better peel strength. Remaining of 100 pieces on the second layer was rated as 5B, remaining of 80 to less than 100 pieces on the second layer was rated as 4B, remaining of 60 to less than 80 pieces on the second layer was rated as 3B, remaining of 40 to less than 60 pieces on the second layer was rated as 2B, and remaining of less than 40 pieces on the second layer was rated as 1B.

(5) Durability when dipped in hot water: Each of the optical films was cut into a square specimen having a size of 10 mm×10 mm (length×width), which in turn was dipped in water at 85° C. and left for 1 hour. Thereafter, separation between the first layer and the second layer and between the first layer and the third layer was evaluated. No separation therebetween was rated as “○” and even slight separation therebetween was rated as “x”.

(6) Reliability of optical film: Each of the optical films was cut into a square specimen having a size of 10 mm×10 mm (length—width), which in turn was left at 85° C. for 500 hours (heat resistance) or at 85° C. and 85% RH for 500 hours (humid-heat resistance). Thereafter, lifting at an end portion, delamination, appearance deformation, and bubble generation were evaluated with the naked eye. No generation of such a phenomenon was rated as “○” and generation of such a phenomenon was rated as “x”.

(7) Reliability of polarizing plate: Each of the polarizing plates was cut into a square specimen having a size of 10 mm×10 mm (length×width), which in turn was left at 85° C. for 500 hours (heat resistance) or at 85° C. and 85% RH for 500 hours (humid-heat resistance). Thereafter, lifting at an end portion, delamination, appearance deformation, and bubble generation were evaluated through the naked eye. No generation of such a phenomenon was rated as “○” and generation of such a phenomenon was rated as “x”.

TABLE 2

| | | | | | | Reliability (6) | | Reliability (7) | |
|---|---|---|---|---|---|---|---|---|---|
| | | | | | | | Humid- | | Humid- |
| | | | Peel | | | Heat | heat | Heat | heat |
| | Tg | Haze | strength | Cross-cut | Durability | resistance | resistance | resistance | resistance |
| Example 1 | 60 | 0.2 | 300 | 5B | ∘ | ∘ | ∘ | ∘ | ∘ |
| Example 2 | 60 | 0.2 | 400 | 5B | ∘ | ∘ | ∘ | ∘ | ∘ |
| Example 3 | 60 | 0.2 | 500 | 5B | ∘ | ∘ | ∘ | ∘ | ∘ |
| Example 4 | 60 | 0.2 | 600 | 5B | ∘ | ∘ | ∘ | ∘ | ∘ |
| Example 5 | 80 | 0.2 | 600 | 5B | ∘ | ∘ | ∘ | ∘ | ∘ |
| Example 6 | 100 | 0.2 | 600 | 5B | ∘ | ∘ | ∘ | ∘ | ∘ |
| Comparative | 45 | 1.0 | 60 | 1B | x | x | x | x | x |
| Example 1 | | | | | | | | | |
| Comparative | −20 | 0.3 | 71 | 2B | ∘ | x | x | x | x |
| Example 2 | | | | | | | | | |
| Comparative | 0 | 0.3 | 103 | 2B | ∘ | ∘ | ∘ | x | x |
| Example 3 | | | | | | | | | |
| Comparative | 65 | 0.3 | 104 | 3B | x | ∘ | ∘ | x | x |
| Example 4 | | | | | | | | | |
| Comparative | 10 | 0.3 | 50 | 2B | ∘ | x | x | x | x |
| Example 5 | | | | | | | | | |
| Comparative | 65 | 0.3 | 50 | 3B | ∘ | x | x | x | x |
| Example 6 | | | | | | | | | |
| Comparative | 0 | 0.2 | 200 | 5B | x | ∘ | ∘ | x | x |
| Example 7 | | | | | | | | | |
| Comparative | 40 | 0.2 | 300 | 5B | x | ∘ | ∘ | x | x |
| Example 8 | | | | | | | | | |

As shown in Table 2, the optical films according to the present invention exhibited low haze and good interlayer peel strength while achieving good adhesion between the primer layer and the retardation layer by providing good cross-cut evaluation results. The optical films according to the present invention exhibited good properties in terms of durability, heat resistance durability, and humid-heat resistance durability upon dipping test in hot water. Further, the polarizing plates including the optical film according to the present invention exhibited good properties in both heat resistance durability and humid-heat resistance durability.

By contrast, the optical films of Comparative Examples 1 to 6, which were prepared without using (meth)acrylate primer layers as the first primer layer and the second primer layer, failed to achieve all of the effects of the present invention. The optical films of Comparative Examples 7 and 8, which were prepared using a (meth)acrylate primer layer having a glass transition temperature not within the inventive range, failed to achieve all of the effects of the present invention.

Although some embodiments have been described herein, it is to be understood that various modifications, changes, alterations, and equivalent embodiments can be made by those skilled in the art without departing from the spirit and scope of the present invention.

What is claimed is:

1. An optical film comprising: a third layer, a second primer layer, a first layer, a first primer layer, and a second layer sequentially stacked in the stated order, wherein each of the first primer layer and the second primer layer has a glass transition temperature (Tg) of 50° C. to 100° C. and is a (meth)acrylate based primer layer.

2. The optical film according to claim 1, wherein the first layer comprises a hydrophobic retardation film.

3. The optical film according to claim 2, wherein the hydrophobic retardation film comprises at least one selected from among a cyclic olefin polymer (COP) based film and a cyclic olefin copolymer (COC) based film.

4. The optical film according to claim 1, wherein the second layer comprises a non-liquid crystal layer having an in-plane retardation of 70 nm to 120 nm at a wavelength of 550 nm.

5. The optical film according to claim 1, wherein the third layer comprises a non-liquid crystal positive C retardation layer.

6. The optical film according to claim 1, wherein each of the second layer and the third layer comprises at least one selected from among a polystyrene based polymer and a cellulose based polymer.

7. The optical film according to claim 6, wherein each of the polystyrene based polymer and the cellulose based polymer contains one or more halogen.

8. The optical film according to claim 7, wherein the halogen is fluorine.

9. The optical film according to claim 1, wherein the first layer has a lower glass transition temperature and a higher Young's modulus than each of the second layer and the third layer.

10. The optical film according to claim 1, wherein the (meth)acrylate based primer layer is formed of a primer layer composition comprising a copolymer of a monomer mixture comprising a (meth)acrylic monomer having a glass transition temperature of 10° C. to 100° C. in a homopolymer phase.

11. The optical film according to claim 10, wherein the (meth)acrylic monomer comprises an alkyl group-containing (meth)acrylic ester.

12. The optical film according to claim 10, wherein the monomer mixture further comprises a peel strength-enhancing compound.

13. The optical film according to claim 12, wherein the peel strength-enhancing compound comprises at least one selected from among methyl (meth)acrylate, ethyl (meth)acrylate, n-propyl (meth)acrylate, iso-propyl (meth)acrylate, n-butyl (meth)acrylate, iso-butyl (meth)acrylate, t-butyl (meth)acrylate, n-hexyl (meth)acrylate, 2-ethylhexyl (meth)acrylate, isobornyl (meth)acrylate, cyclohexyl (meth)acrylate, n-octyl (meth)acrylate, lauryl (meth)acrylate, stearyl (meth)acrylate, butyl acetic ester, butyl formic ester, 2-methyl-2-propenoic acid cyclohexyl ester, 2-propenoic acid 2-methyl-cyclohexyl ester, and isopropyl acetate.

14. The optical film according to claim 13, wherein the peel strength-enhancing compound comprises at least one selected from among butyl acetic ester, butyl formic ester, 2-methyl-2-propenoic acid cyclohexyl ester, 2-propenoic acid 2-methyl-cyclohexyl ester, and isopropyl acetate.

15. The optical film according to claim 10, wherein the primer layer composition further comprises at least one selected from among a peel strength-enhancing compound and a curing agent.

16. The optical film according to claim 1, wherein the optical film has a haze of 0.3% or less, a peel strength of 300 gf/25 mm or more between the first layer and the second layer, and a peel strength of 300 gf/25 mm or more between the first layer and the third layer.

17. A polarizing plate comprising: a polarizer; and the optical film according to claim 1 on at least one surface of the polarizer.

18. An optical display apparatus comprising the polarizing plate according to claim 17.
